(19) United States
(12) Patent Application Publication
(10) Pub. No.: US 2010/0044814 A1
(43) Pub. Date: Feb. 25, 2010

(54) Camera Module and Manufacturing Method Thereof

(75) Inventors: Sheng-Yuan Lin, Taipei Hsien (TW); Nien-Ting Weng, Taipei Hsien (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHENG UEI PRECISION INDUSTRY CO., LTD., Taipei Hsien (TW)

(21) Appl. No.: 12/197,464

(22) Filed: Aug. 25, 2008

(51) Int. Cl. H01L 31/0232; H01L 31/18

(52) U.S. Cl. 257/432; 438/65; 257/E31.127

(57) ABSTRACT

A camera module includes an image sensor chip module and a lens module. The image sensor chip module includes a base, an image sensor chip disposed on the base and electrically connected with the base, and a frame disposed on the base and surrounding the image sensor chip therein. The lens module includes a barrel mounted on the frame of the image sensor chip module and at least two lens units disposed in the barrel respectively. One of the lens units is disposed on the frame and over the image sensor chip and has a transparent cover capable of filtering infrared rays out and a lens attached to a side of the transparent cover such that the transparent cover separates the lens away from the image sensor chip.

### BACKGROUND OF THE INVENTION

1. Field of the Invention

The present invention generally relates to a camera module and manufacturing method thereof, and more particularly to a camera module adapted for a portable electronic device and a method for manufacturing the camera module.

2. The Related Art

Accompanied with the rapid development of electronic technology, various mobile electronic devices such as mobile phones, personal digital assistants, etc. are newly provided with a photo-shooting feature afforded by a camera module mounted therein.

FIG. 1 shows in section a conventional camera module 100 which is disclosed in U.S. patent application publication number 2006/0290802. The camera module 100 includes a lens holder 70, a lens module 80 and an image sensor chip package 90. Both the lens module 80 and the image sensor chip package 90 are mounted with the lens holder 70. The lens holder 70 is a hollow cylinder. The lens module 80 has a barrel 81 and at least one lens 82 received in the barrel 81. The image sensor chip package 90 includes a base 91, an image sensor chip 92 having a photosensitive area 921 disposed on a top surface thereof, and a transparent cover 94. The image sensor chip 92 is disposed on the base 91 and the transparent cover 94 is laid over the image sensor chip 92 through adhesive means 93 used for locating the transparent cover 94 on the base 91, so that the photosensitive area 921 of the image sensor chip 92 is sealed in a space defined by the transparent cover 94 and the adhesive means 93.

A method of manufacturing the camera module 100 includes the following steps of: firstly manufacturing the lens 82 and the transparent cover 94 separately, then assembling the lens 82 in the barrel 81 to form the lens module 80, finally assembling the lens module 80 and the transparent cover 94 together with the lens holder 70 and the base 91 of the image sensor chip package 90.

However, because the lens 82 and the transparent cover 94 are separately manufactured and then assembled with the lens holder 70 and the base 91 of the image sensor chip package 90, in order to avoid interference between the lens 82 and the transparent cover 94, a predetermined interval exists inevitably between the lens 82 and the transparent cover 94. Therefore, the miniaturization of the camera module 100 is hard to realize, and meanwhile, the manufacturing method of the camera module 100 is complicated, which reduces the production efficiency of the camera module 100.

Additionally, each camera module has a function of filtering infrared rays out. Generally, IR-cut coating is plated on one of the lenses of the camera module for filtering the infrared rays out. However, because the lens is made of material such as plastic or aspherical glass, in case that the lens is made of plastic, the lens will fail to withstand high temperature generated during the process of plating the IR-cut coating on the lens, and in case that the lens is made of aspherical glass, it is hard to make the IR-cut coating uniformly be plated on the lens, so that the IR-cut coating cannot but be plated on a piece of plate glass. The piece of plate glass with the IR-cut coating and the lenses are separately mounted in the camera module. In order to prevent floating dust or the like from being attached on the image sensor chip, the camera module has the transparent cover disposed therein and over the image sensor chip. The lenses, the piece of plate glass and the transparent cover are respectively mounted in the camera module, all of which collectively occupy a lot of space of the camera module. Even if the piece of plate glass and the transparent cover can be integrally formed into an entire unit disposed over the image sensor chip, because the predetermined interval exists between the lens and the unit, the miniaturization and the image quality of the camera module are affected inevitably.

### SUMMARY OF THE INVENTION

Accordingly, an object of the present invention is to provide a camera module which is smaller in size compared with conventional module and a method for manufacturing the camera module. The camera module includes an image sensor chip module and a lens module. The image sensor chip module includes a base, an image sensor chip disposed on the base and electrically connected with the base, and a frame disposed on the base and surrounding the image sensor chip therein. The lens module includes a barrel mounted on the frame of the image sensor chip module and at least two lens units disposed in the barrel respectively. One of the lens units is disposed on the frame and located over the image sensor chip and has a transparent cover capable of filtering infrared rays out and a lens attached to a side of the transparent cover such that the transparent cover separates the lens away from the image sensor chip.

The method for manufacturing the camera module includes steps of: forming a plurality of lenses attached to a side of a transparent board capable of filtering infrared rays out, and dividing the combination of the transparent board and the lenses into plural individual lens units such that each of the lens units includes a transparent cover attained by dividing the transparent board and one of the lenses positioned on the transparent cover.

As described above, because the lens and the transparent cover are formed together as a whole, the camera module is reduced in dimension and the reliability of the camera module is enhanced.

In manufacturing the camera module, the lenses are integrally formed on the transparent board and then the combination of the lenses and the transparent board is divided into a plurality of the lens units to be assembled on the image sensor chip module, which increases the production efficiency of the camera module.

### BRIEF DESCRIPTION OF THE DRAWINGS

The present invention will be apparent to those skilled in the art by reading the following description of preferred embodiments thereof, with reference to the accompanying drawings, in which:

FIG. 1 is a cross-sectional view of a prior camera module;

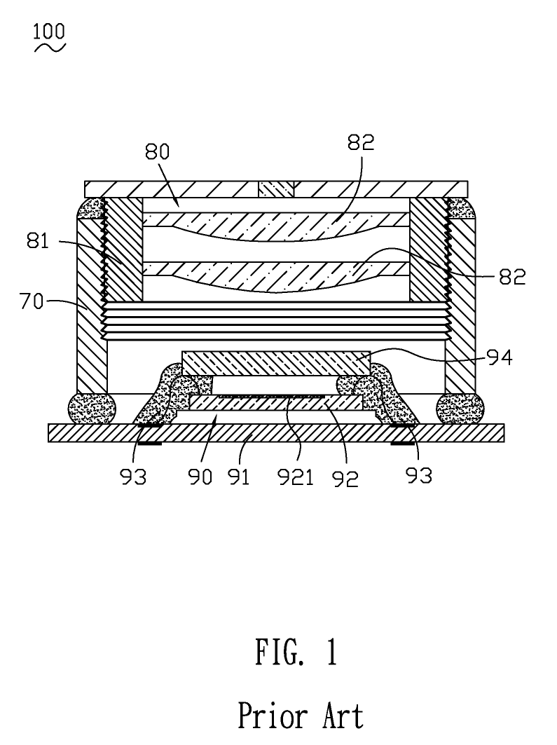

FIG. 2 is a cross-sectional view of a camera module according to a first embodiment of the present invention;

FIG. 3 is a cross-sectional view of a camera module according to a second embodiment of the present invention;

FIG. 4 is a schematic view showing a first manufacturing method of the camera module according to the embodiments of the present invention; and

FIG. 5 is a schematic view showing a second manufacturing method of the camera module according to the embodiments of the present invention.

### DETAILED DESCRIPTION OF THE PREFERRED EMBODIMENTS

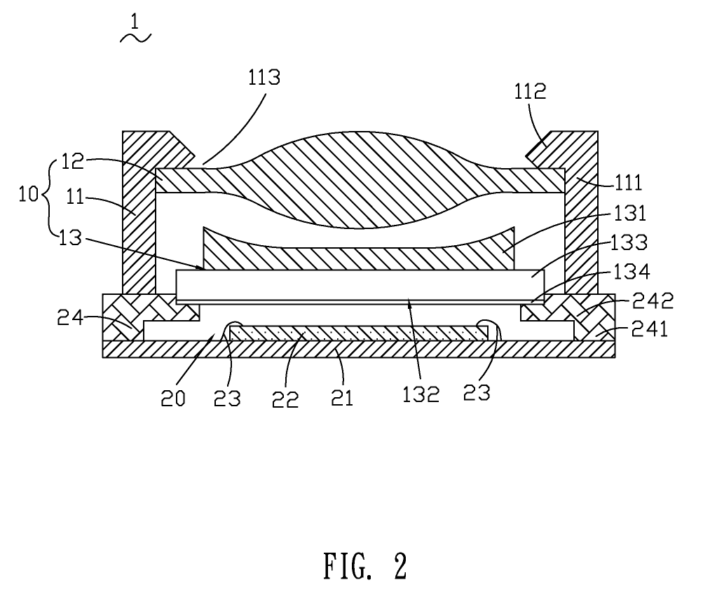

Referring to FIG. 2, a camera module 1 in accordance with a first embodiment of the present invention includes a lens module 10 and an image sensor chip module 20 engaged with the lens module 10.

The lens module 10 includes a barrel 11 and at least two lens units, i.e., an upper lens unit 12 and a lower lens unit 13. The upper lens unit 12 and the lower lens unit 13 are both made of material capable of withstanding high temperature and respectively disposed in top and bottom portions of the barrel 11. The lower lens unit 13 has a lens 131 and an IR-cut transparent cover 132 capable of filtering infrared ray out of the incident rays. In the first embodiment of the present invention, the IR-cut transparent cover 132 is a piece of plate glass 133 a bottom surface of which is plated by an IR-cut coating 134 for filtering the infrared ray purpose. On a top surface of the piece of plate glass 133, the lens 131 is supported.

The barrel 11 has an enclosure 111 of for example a hollow cylindrical shape. A cylindrical receiving space 113 communicating with the outside at top and bottom portions of the enclosure 111 is defined axially inside the enclosure 111. The top portion of the enclosure 111 protrudes radially inwardly to form a circular extending portion 112. The at least two lens units 12, 13 are respectively received in the receiving space 113 and disposed at the top and bottom portions of the receiving space 113. The upper lens unit 12 is also disposed underneath the extending portion 112.

The image sensor chip module 20 has a base 21, an image sensor chip 22, a plurality of signal wires 23 and a frame 24. The image sensor chip 22 is mounted on a top surface of the base 21. The signal wires 23 electrically connect the image sensor chip 22 with the base 21 for signal transmission. The frame 24 has a supporting portion 241 located on the top surface of the base 21 and a bearing portion 242 extending inward from a top portion of the supporting portion 241 for supporting the IR-cut transparent cover 132 of the lens module 10 thereon. The bottom surface of the piece of plate glass 133 plated by the IR-cut coating 134 is closer to the image sensor chip 22 than the top surface of the piece of plate glass 133. The base 21, the frame 24 and the IR-cut transparent cover 132 of the lens module 10 define together a sealed space to receive the image sensor chip 22 therein for preventing floating dust or the like from falling in the sealed space and being attached to the image sensor chip 22. The barrel 11 of the lens module 10 is mounted on the bearing portion 242 of the frame 24. The image sensor chip 22 is aligned with an optical axis of the at least two lens units 12, 13.

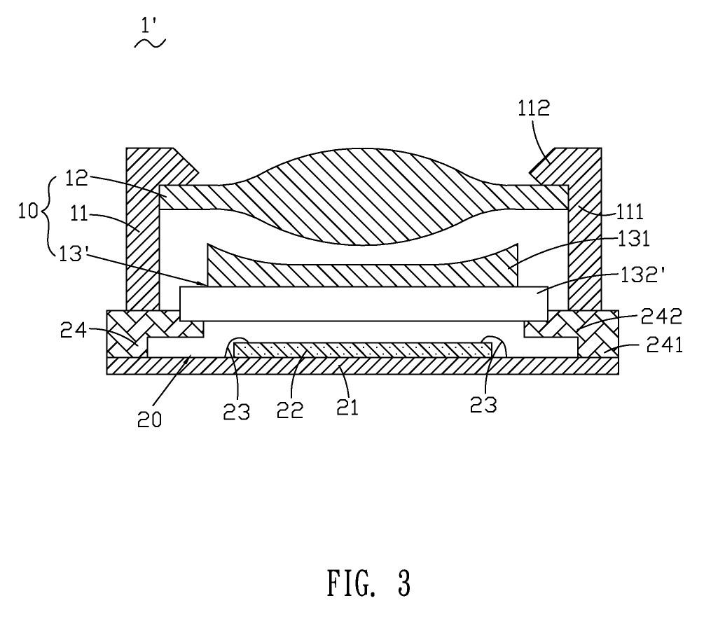

Referring to FIG. 3, a camera module 1′ of a second embodiment of the present invention has a similar structure to the camera module 1 of the first embodiment of the present invention. The same structure of the camera module 1′ of the second embodiment to the camera module 1 of the first embodiment is omitted hereinafter and not described once again for simplicity. The difference between the camera module 1′ of the second embodiment and the camera module 1 of the first embodiment is that the camera module 1′ of the second embodiment has a lower lens unit 13′. The lower lens unit 13′ has the lens 131 and an IR-cut transparent cover 132′ capable of filtering infrared rays out. In the second embodiment, the IR-cut transparent cover 132′ is made of glass having a property of filtering the infrared rays out, and accordingly, it is unnecessary for the IR-cut transparent cover 132′ to be plated by the IR-cut coating 134.

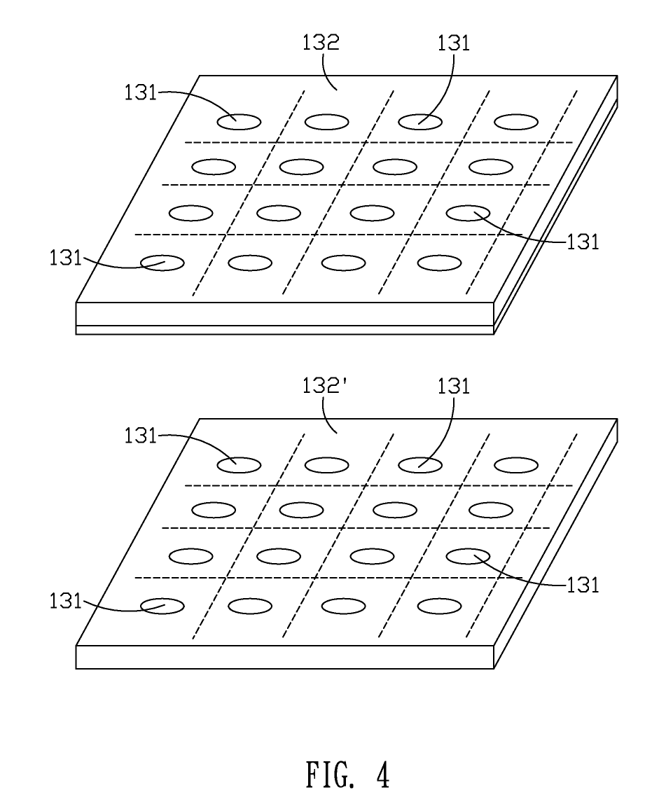

With reference to FIG. 4 together with FIG. 2 and FIG. 3, a first manufacturing method of the camera module 1, 1′ is described as follows:

Firstly, fluid material having a property of optical imaging is coated and solidified on a top surface of a big piece of IR-cut transparent board to form a plurality of lenses 131 integrated with the IR-cut transparent board. The lenses 131 have the same shape and size and are arranged in a matrix form on the top surface of the IR-cut transparent board.

Secondly, the combination of the IR-cut transparent board and the lenses 131 is divided into a plurality of the lower lens units 13, 13′ along the dotted line shown in FIG. 4. Each of the lower lens units 13, 13′ has one of the lenses 131 and one corresponding IR-cut transparent cover 132, 132′ attained by dividing the IR-cut transparent board.

Thirdly, the lower lens unit 13, 13′ is disposed on the bearing portion 242 of the frame 24 over the image sensor chip 22, and then the frame 24 is disposed on the base 21.

Lastly, the barrel 11 receiving the upper lens unit 12 is disposed on the bearing portion 242 of the frame 24 and receives the lower lens unit 13, 13′ therein.

Obviously, after the second step of the first manufacturing method of the camera module 1, 1′, another feasible way is that the frame 24 is firstly disposed on the base 21, and then the lower lens unit 13, 13′ is disposed on the bearing portion 242 over the image sensor chip 22. At last, the barrel 11 is disposed on the bearing portion 242.

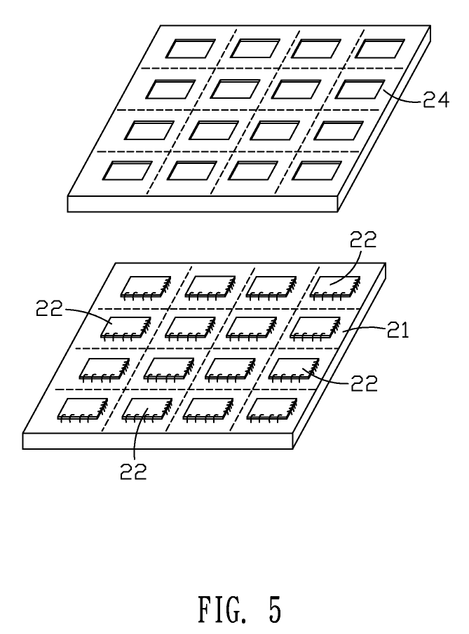

Referring to FIG. 5 together with FIG. 2 and FIG. 3, a second manufacturing method of the camera module 1, 1′ is described as follows. A first step of the second manufacturing method is as same as the first step of the first manufacturing method described above, so the first step of the second manufacturing method is omitted hereinafter. A second step of the second manufacturing method is that a plurality of the image sensor chips 22 is disposed on a top surface of a big piece of substrate in a matrix form, and then an integer made up of a plurality of the frames 24 is disposed on the substrate.

Thirdly, the IR-cut transparent board is disposed on the frames 24 over the corresponding image sensor chips 22, and then the combination of the substrate, the frames 24 and the IR-cut transparent board is divided into a plurality of units, and each of the units contains one lower lens unit 13, 13′ and one image sensor chip module 20.

Lastly, the barrel 11 receiving the upper lens unit 12 is disposed on the bearing portion 242 of the frame 24 and receives the lower lens unit 13, 13′ therein.

As described above, because the lens 131 and the IR-cut transparent cover 132, 132′ are formed together as an unitary body, no space is defined between the lens 131 and the IR-cut transparent cover 132, 132′, and therefore, the camera modules 1, 1′ become compact with respect to conventional modules and the reliability of the camera module 1, 1′ is improved.

In manufacturing the camera module 1, 1′, the lenses 131 are integrally formed on the IR-cut transparent board as an entity and then the combination of the lenses 131 and the IR-cut transparent board is divided into a plurality of the lower lens units 13, 13′ to be assembled on the image sensor chip module 20, which increases the production efficiency of the camera module 1, 1′.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

1. A camera module, comprising:
an image sensor chip module including a base, an image sensor chip disposed on the base and electrically connected with the base, and a frame positioned on the base and surrounding the image sensor chip therein; and
a lens module including a barrel mounted on the frame of the image sensor chip module and at least two lens units disposed in the barrel respectively, a first lens unit being positioned on the frame and located over the image sensor chip and having a transparent cover capable of filtering infrared rays out and a second lens unit attached to an inner side of the barrel and disposed underneath a circular extending portion of an enclosure of the barrel such that the transparent cover separates the second lens unit away from the image sensor chip,
wherein the frame has a supporting portion located on the base and a bearing portion having a longitudinal axis horizontally extending inward from the supporting portion providing support to hold the transparent cover and the first lends unit in place, and the barrel and the first lens unit are disposed on the bearing portion.

2. The camera module as claimed in claim 1, wherein the transparent cover and the lens are integrally formed together.

3. The camera module as claimed in claim 1, wherein the transparent cover is plated by an IR-cut coating on an opposite side thereof facing the image sensor chip for filtering the infrared rays out.

4. The camera module as claimed in claim 1, wherein the transparent cover is made of glass having a property of filtering the infrared rays out.

5. (canceled)

6. A manufacturing method of a camera module, comprising:
forming a plurality of lenses attached to a side of a transparent board capable of filtering infrared rays out; and
dividing the combination of the transparent board and the lenses into plural individual lens units such that each of the lens units includes a transparent cover attained by dividing the transparent board and one of the lenses positioned on the transparent cover.

7. The manufacturing method of the camera module as claimed in claim 6, wherein the lenses are formed on the transparent board in a matrix form.

8. The manufacturing method of the camera module as claimed in claim 6, wherein the lenses are formed by coating and then solidifying fluid material having a property of optical imaging on the transparent board.

9. A manufacturing method of a camera module, comprising:
forming a plurality of lenses attached to a side of a transparent board capable of filtering infrared rays out;
bonding a combination made up of a plurality of frames and a plurality of image sensor chips on a substrate;
disposing the transparent board on the frames; and
dividing the combination of the transparent board, the frames and the substrate into plural individual units such that each of the units includes a transparent cover attained by dividing the transparent board, one of the lenses, one of the frames, one of the image sensor chips and a base attained by dividing the substrate.
